(19) United States
(12) Patent Application Publication
(10) Pub. No.: US 2025/0136440 A1
(43) Pub. Date: May 1, 2025

(54) METHOD FOR FORMING A BORE FOR A CAVITY ARRANGED WITHIN A SEMICONDUCTOR LAYER STACK

(71) Applicant: Robert Bosch GmbH, Stuttgart (DE)

(72) Inventor: Johannes Classen, Reutlingen (DE)

(21) Appl. No.: 18/910,687

(22) Filed: Oct. 9, 2024

(30) Foreign Application Priority Data
Oct. 26, 2023 (DE) 10 2023 210 570.5

(51) Int. Cl. B81C 1/00; B81B 7/00

(52) U.S. Cl. CPC B81C 1/00515; B81B 7/0041; B81C 2201/0143

(57) ABSTRACT

A method for forming a bore for a cavity within a semiconductor layer stack. The method includes forming a first partial bore using a first laser ablation step starting at an outer surface of the stack so that the first partial bore extends with a first mean dimension and aligned in parallel with the outer surface, starting from the outer surface, and a bottom surface of the first partial bore lying between the outer surface and the cavity, and forming a second partial bore using a second laser ablation step started from the bottom surface of the first partial bore so that the second partial bore extends with a second mean dimension, aligned in parallel with the outer surface and is smaller than the first mean dimension, through the bottom surface into the cavity or an access channel opening at the cavity or connected to the cavity.

### CROSS REFERENCE

The present application claims the benefit under 35 U.S.C. § 119 of German Patent Application No. DE 10 2023 210 570.5 filed on Oct. 26, 2023, which is expressly incorporated herein by reference in its entirety.

### FIELD

The present invention relates to a method for forming a bore for a cavity arranged within a semiconductor layer stack. The present invention also relates to a method for enclosing a pressure and/or a medium in a cavity arranged within a semiconductor layer stack. Furthermore, the present invention relates to semiconductor layer stacks.

### BACKGROUND INFORMATION

German Patent Application No. DE 10 2011 103 516 A1 describes a method for filling a chamber with an atmosphere. The chamber arranged within a semiconductor layer stack is subsequently filled by material being removed by laser ablation by means of a pulsed laser beam. In this way, an opening with a (substantially) constant opening diameter is created, which extends into the interior of the chamber. Once the chamber has been filled with the desired atmosphere, the opening is sealed by melting and subsequent solidification by means of a further laser beam, which causes slow heating in the region of the opening.

### SUMMARY

The present invention provides a method for forming a bore for a cavity arranged within a semiconductor layer stack, a method for enclosing a pressure and/or a medium in a cavity arranged within a semiconductor layer stack, a semiconductor layer stack, and a semiconductor layer stack.

The present invention allows for a cost-effective and easily executable production of a plurality of semiconductor devices that comprise a cavity having a desired internal pressure and/or a defined medium within the particular cavity within a semiconductor layer stack of the particular semiconductor device. In particular, by means of the use of the present invention, problems that conventionally frequently occur due to the execution of at least one etching process for forming a bore up to the particular cavity can be avoided. Furthermore, the present invention realizes an improved laser drilling technique compared to the related art for forming a bore up to the cavity or up to an access channel connected thereto, as a result of which the particular bore can be formed more rapidly and an incidence of particles or fumes occurring in the cavity due to laser drilling is significantly reduced. By means of the use of the present invention, damage to the semiconductor devices caused by particles or fumes generated during laser drilling can be reduced compared to conventional techniques.

In the case of an advantageous example embodiment of the method of the present invention, the first partial bore and the second partial bore are drilled through a semiconductor substrate of the semiconductor layer stack bounding the cavity, which substrate is equipped, on its substrate surface directed away from the outer surface of the semiconductor layer stack, with a circuit layer having at least one application-specific integrated circuit. The semiconductor substrate equipped with the at least one application-specific integrated circuit can also be referred to as an ASIC substrate. In particular, the outer surface of the semiconductor layer stack can be a rear side of the ASIC substrate directed away from the substrate surface having the at least one application-specific integrated circuit. Drilling the first partial bore and the second partial bore through the ASIC substrate is much easier and less expensive than alternatively drilling access holes through a MEMS substrate, since a substrate thickness of the ASIC substrate aligned perpendicularly to the outer surface is generally significantly smaller than a corresponding substrate thickness of a MEMS substrate. Therefore, in the case of the embodiment described here, the formation of the bore comprising the first partial bore and the second partial bore through the ASIC substrate can be effected within shorter process times.

Alternatively, the first partial bore and the second partial bore can also be drilled through a capping substrate of the semiconductor layer stack, which capping substrate bounds the cavity. A substrate thickness of the capping substrate aligned perpendicularly to the outer surface is also generally comparatively thin, which is why the advantages of a comparatively short process time for forming the bore comprising the first partial bore and the second partial bore are also ensured in this case.

Preferably, according to an example embodiment of the present invention, the second partial bore is drilled into the access channel extending in parallel with the outer surface of the semiconductor layer stack through a part of the semiconductor layer stack. As can be seen from the following description, in this case the access channel prevents the penetration of particles or fumes into the cavity.

In the case of a further advantageous embodiment of the method, the first partial bore and the second partial bore are aligned with respect to one another in such a way that a common central longitudinal axis can be defined for the first partial bore and the second partial bore. Preferably in this case, a first length of the first partial bore along the common central longitudinal axis is greater by at least a factor of 2 than a second length of the second partial bore along the common central longitudinal axis. As can be seen from the following description, even with a comparatively large sum of the first length and the second length, the bore comprising the first partial bore and the second partial bore can be formed relatively rapidly.

According to an example embodiment of the present invention, it is advantageous if the first partial bore is formed with the first mean dimension aligned in parallel with the outer surface, which dimension is greater by at least a factor of 2 than the second mean dimension, with which the second partial bore is formed in parallel with the outer surface. Thus, the first laser ablation step can be executed at a high ablation speed, while the second laser ablation step can be executed at a significantly reduced ablation speed.

The advantages described above are also ensured when executing a method for enclosing a pressure and/or a medium in a cavity arranged within a semiconductor layer stack, comprising the steps of: forming a bore for the cavity arranged within the semiconductor layer stack according to one embodiment of the method explained above, and sealing the bore when the pressure and/or the medium are present in the cavity by melting a wall region of the first partial bore and/or the second partial bore of the bore, which wall region lies adjacent to the bottom surface of the first partial bore of the bore, by means of a laser beam.

### BRIEF DESCRIPTION OF THE DRAWINGS

Further features and advantages of the present invention will be explained in the following with reference to the figures.

FIG. 1A to 1C are schematic representations of intermediate or final products for illustrating a first example embodiment of the method according to the present invention for forming a bore for a cavity arranged within a semiconductor layer stack.

FIG. 2A and 2B are schematic representations of intermediate or final products for illustrating a second example embodiment of the method of the present invention for forming a bore for a cavity arranged within a semiconductor layer stack.

FIG. 3A and 3B are schematic representations of intermediate or final products for illustrating a third example embodiment of the method of the present invention for forming a bore for a cavity arranged within a semiconductor layer stack.

FIG. 4 is a schematic representation of a final product for illustrating a fourth example embodiment of the method of the present invention for forming a bore for a cavity arranged within a semiconductor layer stack.

### DETAILED DESCRIPTION OF EXAMPLE EMBODIMENTS

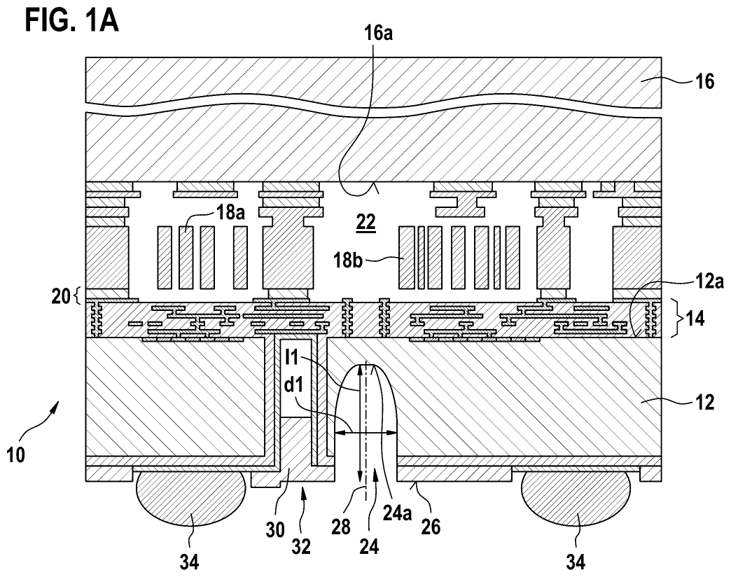

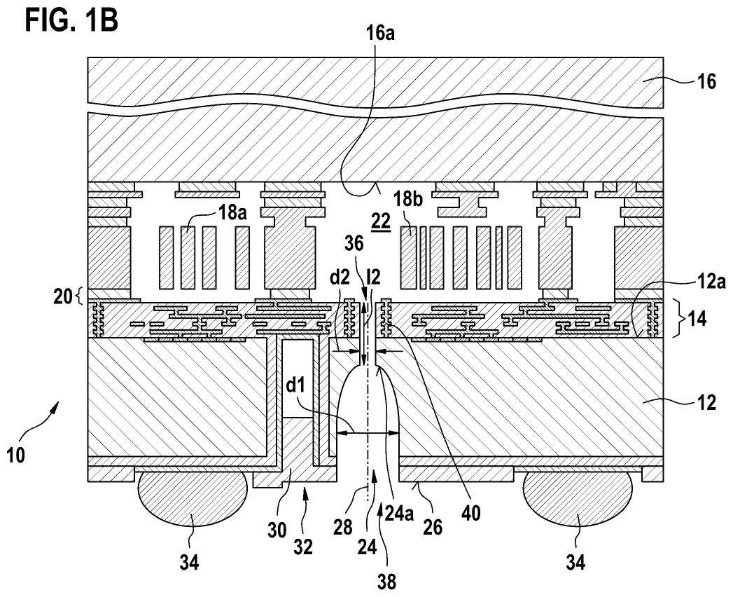

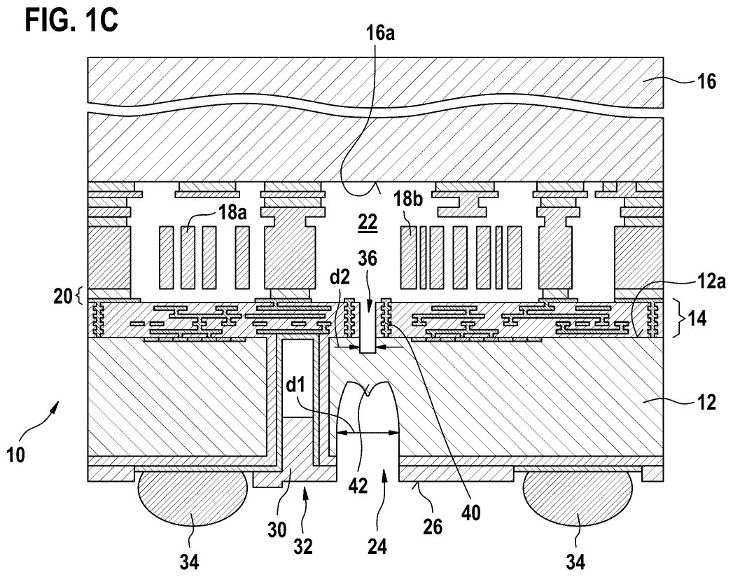

FIG. 1A to 1C are schematic representations of intermediate or final products for illustrating a first embodiment of the method for forming a bore for a cavity arranged within a semiconductor layer stack.

In the case of the embodiment described here, the semiconductor layer stack 10 comprises, by way of example, a so-called ASIC substrate 12, the substrate surface 12a of which is equipped with a circuit layer 14 having at least one application-specific integrated circuit, and a so-called MEMS substrate 16 having at least one MEMS component 18a and 18b fastened/connected to a substrate surface 16a of the MEMS substrate 16. The circuit layer 14 can, e.g., be designed as a CMOS layer 14. The at least one MEMS component 18a and 18b can be understood to be at least one MEMS sensor 18a and 18b and/or at least one MEMS actuator. The at least one MEMS sensor 18a and 18b can be, for example, a rotation rate sensor 18a, an acceleration sensor 18b and/or a pressure sensor. However, the sensor types listed here should only be interpreted by way of example. By way of example, in the case of the embodiment described herein, the ASIC substrate 12 and the MEMS substrate 16 are connected to one another via at least one bond connection 20 in such a way that the substrate surfaces 12a and 16a are aligned with respect to one another and a cavity 22 is enclosed between the circuit layer 14 and the substrate surface 16a of the MEMS substrate 16. However, it should be pointed out that this semiconductor layer stack 10 is only to be interpreted by way of example. The method described below can be executed with a plurality of further semiconductor layer stacks, in each case with a cavity 22 arranged within the particular semiconductor layer stack.

As illustrated in FIG. 1A, when the method described herein is executed, a first partial bore 24 is first formed by means of a first laser ablation step started at an outer surface 26 of the semiconductor layer stack 10. The first laser ablation step can also be understood as a laser ablation step or a laser vaporization step. For better understanding, the outer surface 26 of the semiconductor layer stack 10, at which the formation of the first partial bore 24 is started by means of the first laser ablation step, is hereinafter referred to as the bore exit surface 26. By means of the first laser ablation step, the first partial bore 24 is formed in such a way that the first partial bore 24 extends with a first mean dimension d1, which is aligned in parallel with the bore exit surface 26, partially through the semiconductor layer stack 10 starting from the bore exit surface 26. Furthermore, the first partial bore 24 is formed by means of the first laser ablation step on a side which is directed away from the bore exit surface 26 and has a bottom surface 24a of the first partial bore 24 which lies between the bore exit surface 26 and the cavity 22.

The first laser ablation step can be executed with a first laser optimized for high ablation, which is why the first laser ablation step can be executed comparatively rapidly in relation to a first length 11 of the first partial bore 24 extending along a central longitudinal axis 28 of the first partial bore 24. In particular, the first laser ablation step is significantly more rapid and much easier to execute than an etching step for achieving the same first length 11 of the first partial bore 24. Since the first laser ablation step is stopped before the bottom surface 24a of the first partial bore 24 reaches the cavity 22, even if the first high ablation laser is used for executing the first laser ablation step, there is no risk of particles penetrating into the cavity 22 during the first laser ablation step.

As can be seen in FIG. 1A, the first partial bore 24 can be formed in the shape of a blind hole or a cup-shaped trench, in particular such that an opening diameter of the first partial bore 24 at the bore exit surface 26 is comparatively large. However, the opening diameter of the first partial bore 24 at the bore exit surface 26 is generally still smaller than the first length 11 of the first partial bore 24 extending along the central longitudinal axis 28 of the first partial bore 24. The central longitudinal axis 28 of the first partial bore 24 can in particular be aligned perpendicularly to the bore exit surface 26.

In particular, the bore exit surface 26 can also be understood as an outer surface 26 of a passivation layer 30. It is expressly pointed out here that the formation of the first partial bore 24 can also only be started if at least one through-contact 32 (TSV) adjacent to the later first partial bore 24 already extends partially through the semiconductor layer stack 10 starting from the bore exit surface 26 in the direction of the cavity 22 and/or if at least one solder ball 34 is fastened to the semiconductor layer stack 10 adjacent to and/or at the bore exit surface 26. It can also be seen based on FIG. 1A that the formation of the first partial bore 24 can also be effected after an advanced packaging process.

As shown in FIG. 1B, after the formation of the first partial bore 24, a second partial bore 36 is formed by means of a second laser ablation step started from the bottom surface 24a of the first partial bore 24. The second laser ablation step can also be a laser ablation step or a laser vaporization step. The second partial bore 36 is formed in such a way that the second partial bore 36 extends with a second mean dimension d2, which is aligned in parallel with the bore exit surface 26 and is smaller than the first mean dimension d1, through the bottom surface 24a of the first partial bore 24 into the cavity 22 or into an access channel (not sketched) opening at the cavity 22 or connected to the cavity 22 via a connecting channel. The first partial bore 24 and the second partial bore 36 thus together form a bore 38 which, starting from the bore exit surface 26, extends (at least) into the cavity 22 or into the access channel opening at the cavity 22 or connected to the cavity 22 via the connecting channel.

The two laser ablation steps are preferably executed with two different laser configurations. Preferably, a second laser having a lower ablation speed compared to the first laser is used for the second laser ablation step, e.g., because the second laser emits a shorter wavelength than the first laser. In this way, the first partial bore 24 can easily be formed with the first mean dimension d1 aligned in parallel with the bore exit surface 26, which dimension is greater by at least a factor of 2 than the second mean dimension d2, with which the second partial bore 36 is formed in parallel with the bore exit surface 26. Preferably, the second mean dimension d2 is less than or equal to 20 μm (micrometers), in particular less than or equal to 15 μm (micrometers), especially less than or equal to 10 μm (micrometers).

Due to the formation of the second partial bore 36 with the smaller second mean dimension d2 (compared to the first mean dimension d1 of the first partial bore 24), there is no/hardly any risk of particles or fumes penetrating into the cavity 22 during the formation of the second partial bore 36, despite a wall surface of the cavity 22 or of the access channel (opening at the cavity 22 or connected to the cavity 22 via the connecting channel) being broken through. This is a significant advantage of the method described here compared to the related art described above.

The first partial bore 24 and the second partial bore 36 can be aligned with respect to one another in such a way that the central longitudinal axis 28 of the first partial bore 24 can be defined as the common central longitudinal axis 28 of the first partial bore 24 and the second partial bore 36. Furthermore, it is advantageous if the first length 11 of the first partial bore 24 along the common central longitudinal axis 28 is greater by at least a factor of 2 than a second length 12 of the second bore 36 along the common central longitudinal axis 28, because if applicable, even if the second laser has a relatively low ablation speed, a total time for executing the two laser ablation steps is comparatively short. In particular, the two laser ablation steps can be executed within a shorter total time than one etching step for forming a reference bore with a length equal to a sum of the lengths 11 and 12. The execution of the first laser ablation step and the second laser ablation step is also extremely cost-effective compared to executing conventional etching processes.

In the case of an advantageous embodiment of the method described herein, the first partial bore 24 and the second partial bore 36 are drilled through the ASIC substrate 12 of the semiconductor layer stack 10 bounding the cavity 22, wherein the substrate surface 12a having the circuit layer 14 faces away from the bore exit surface 26. The ASIC substrate 12 can have a substrate thickness aligned perpendicularly to the bore exit surface 26 of less than 150 μm (micrometers), specifically less than 80 μm (micrometers), in particular less than 50 μm (micrometers). As can also be seen from FIG. 1B, the bore 38 can extend through the circuit layer 14 within a seal ring 40, as a result of which the formation of cracks in the circuit layer 14 can be limited. In the case of an alternative embodiment, the first partial bore 24 and the second partial bore 36 can also extend through a capping substrate (not shown) of the semiconductor layer stack 10, which substrate bounds the cavity 22. If applicable, a substrate thickness of the capping substrate is preferably less than 150 μm (micrometers), especially less than 80 μm (micrometers), in particular less than 50 μm (micrometers). In both cases, the total time required for executing the first laser ablation step and the second laser ablation step is comparatively short. Optionally, the bore 38 can also be formed through the MEMS substrate 16, wherein the entire volume of the circuit layer 14 can be used for application-specific integrated circuit elements if applicable.

A semiconductor layer stack 10 produced by means of the method steps described above can be seen at a cavity 22 arranged within the semiconductor layer stack 10 and a bore 38, if the bore 38 comprises a first partial bore 24 having laser ablation tracks and a second partial bore 36 having laser ablation tracks, wherein the first partial bore 24 extends with a first mean dimension d1, which is aligned in parallel with an outer surface 26 of the semiconductor layer stack 10, partially through the semiconductor layer stack 10 starting from the outer surface 26 and comprises at least remnants of a bottom surface 24a of the first partial bore 24 lying between the outer surface 26 and the cavity 22, on a side directed away from the outer surface 26, and wherein the second partial bore 36 extends with a second mean dimension d2, which is aligned in parallel with the outer surface 26 and is smaller than the first mean dimension d1, through the bottom surface 24a of the first partial bore 24 into the cavity 22 or into an access channel opening at the cavity 22 or connected to the cavity 22 via a connecting channel (see FIG. 1B).

As an (optional) further development, the method described herein can be part of a method for enclosing a pressure and/or a medium in the cavity 22 arranged within the semiconductor layer stack 10. If applicable, as shown in FIG. 1C, after forming the bore 38, this bore 38 is sealed when the preferred pressure and/or the desired medium is present in the cavity 22. The bore 38 is sealed by melting a wall region of the first partial bore 24 and/or the second partial bore 36, which wall region is adjacent to the bottom surface 24a of the first partial bore 24, by means of a laser beam. The remaining remnants of the partial bores 24 and 36 are generally not critical for any further processing of the end product illustrated in FIG. 1C.

Therefore, the method described herein can be used for producing a plurality of semiconductor devices having a cavity 22 arranged within their particular semiconductor layer stack 10, said cavity having a preferred pressure and/or medium, at a favorable cost. The fact that the particular semiconductor device is produced by executing the method described here can be seen from its semiconductor layer stack 10 having a cavity 22 arranged within the semiconductor layer stack 10 and a bore closure 42 made from a melted and solidified partial material of the semiconductor layer stack 22, which lies between a first partial bore 24 having laser ablation tracks and a second partial bore 38 having laser ablation tracks, wherein the first partial bore 24 extends with a first mean dimension d1, which is aligned in parallel with an outer surface 26 of the semiconductor layer stack 10, partially through the semiconductor layer stack 10 starting from the outer surface 26, and the second partial bore 36 extends with a second mean dimension d2, which is aligned in parallel with the outer surface 26 and is smaller than the first mean dimension d2, into the cavity 22 or into an access channel opening at the cavity 22 or connected to the cavity 22 via a connecting channel (see FIG. 1C).

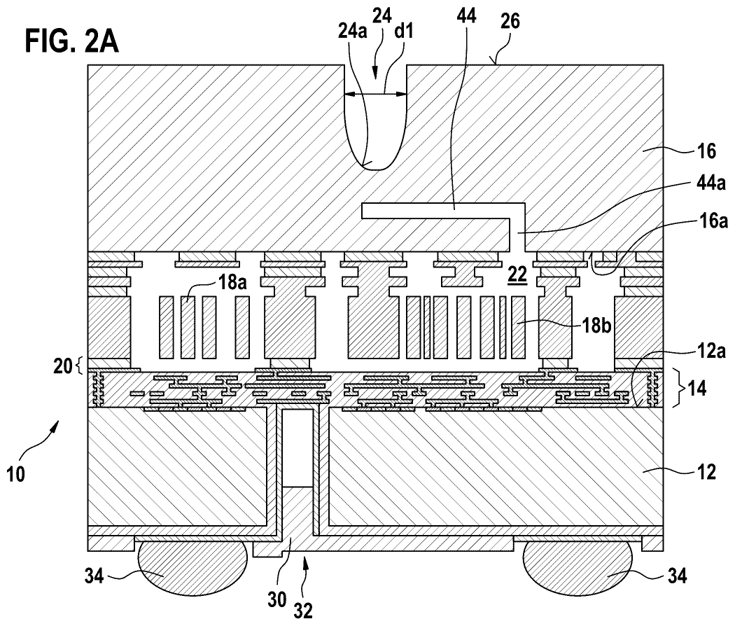

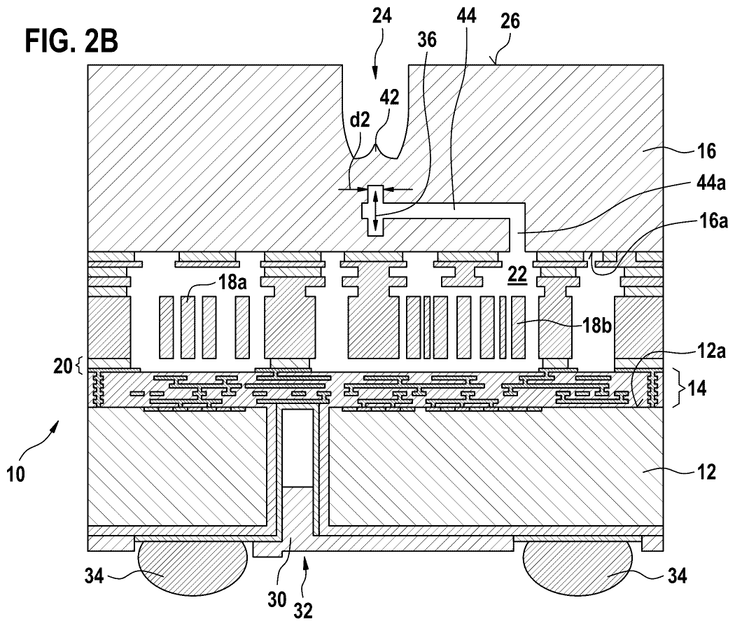

FIG. 2A and 2B are schematic representations of intermediate or final products for illustrating a second embodiment of the method for forming a bore for a cavity arranged within a semiconductor layer stack.

In the case of the method described herein, the second partial bore 36 is drilled into an access channel 44 which extends in parallel with the bore exit surface 26 through a part of the semiconductor layer stack 10, and opens at the cavity 22 or is connected to the cavity 22 via a connecting channel 44a. Due to its alignment, the access channel 44 can also be described as a lateral access channel 44. The alignment of the access channel 44 thus ensures that any particles or fumes released during drilling of the second partial bore 36 are hardly able to enter the cavity 22. In particular, damage to the at least one MEMS component 18a and 18b in the cavity 22 by particles and fumes can be effectively avoided in this way. Thus, a preferred pressure and/or a desired medium can be ensured in the cavity 22 via the access channel 44, while at the same time (substantially) preventing the unwanted penetration of particles and fumes into the cavity 22.

As can be seen in FIG. 2A, the access channel 44 extending in parallel with the bore exit surface 26 through the part of the semiconductor layer stack 10 can be formed in a substrate 16, which is located on a side of the cavity 22 aligned with the bore exit surface 26, in particular adjacent to the cavity 22. In the example in FIG. 2A, the corresponding substrate 16 is the MEMS substrate 16 solely by way of example.

As shown in FIG. 2B, in the case of the method described herein, a desired pressure and/or a preferred medium can also be enclosed in the cavity 22 after completion of the bore 38 comprising the first partial bore 24 and the second partial bore 36, by a wall region of the first partial bore 24 and/or the second partial bore 36 lying adjacent to the bottom surface 24a of the first partial bore 24 subsequently being melted by means of a laser beam, so that the melted material solidifies to form a bore closure 42 sealing the bore 38. It can also be seen in FIG. 2B that in the case of the method described here, the bore 38 is stopped so far away from the cavity 22 that there is no risk of damage to the at least one MEMS component 18a and 18b arranged in the cavity 22 and/or an application-specific integrated circuit formed adjacent to the cavity 22.

With respect to further features of the method shown in FIG. 2A and 2B and its advantages, reference is made to the explanations for FIG. 1A to 1C.

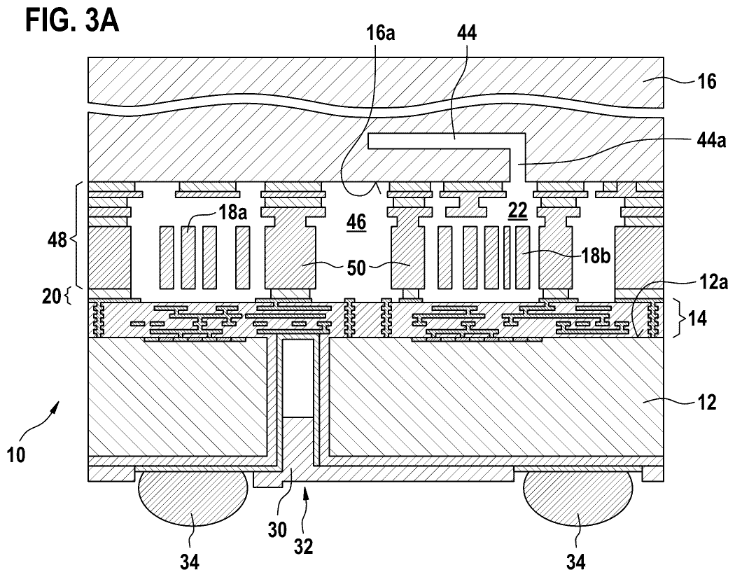

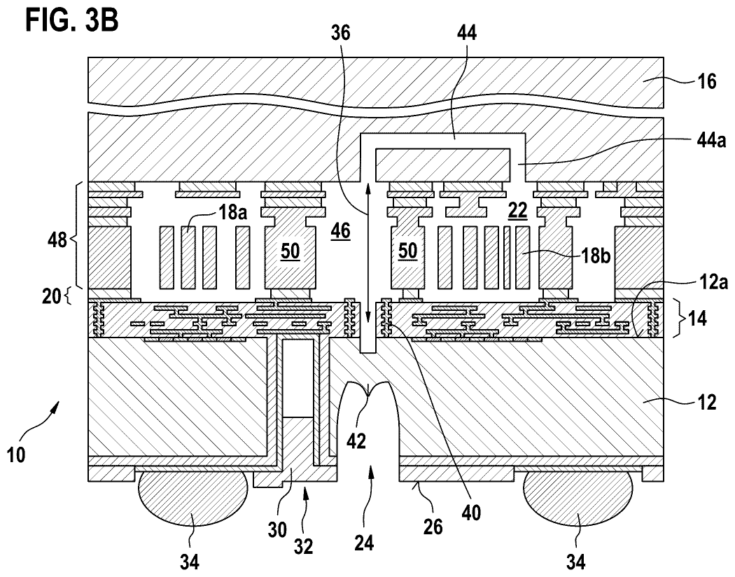

FIG. 3A and 3B are schematic representations of intermediate or final products for illustrating a third embodiment of the method for forming a bore for a cavity arranged within a semiconductor layer stack.

In contrast to the above-described embodiment, in the case of the method of FIG. 3A and 3B, the bore 38 is drilled into the access channel 44 extending in parallel with the bore exit surface 26 through the part of the semiconductor layer stack 10 formed in a substrate 16, which is located on a side of the cavity 22 directed away from the bore exit surface 26 (see FIG. 3A). As can be seen in FIG. 3B, the bore 38 thus also extends through a chamber 46 surrounded by the semiconductor layer stack 10 (even prior to the formation of the first partial bore 24).

Preferably, the chamber 46 lies together with the cavity 22 in a common plane 48 of the semiconductor layer stack 10, but is sealed off from the cavity 22 in a particle-tight or air-tight manner within the common plane by means of at least one partition wall component 50. Thus, there is no/hardly any risk of particles or fumes generated by laser drilling penetrating through the chamber 46 into the cavity 22. The plane 48 formed with the chamber 46 and the cavity 22 can be understood in particular as a plane 48 of the semiconductor layer stack 10 lying between two substrates 12 and 16, such as specifically the ASIC substrate 12 and the MEMS substrate 16.

With respect to further features of the method shown in FIG. 3A and 3B and its advantages, reference is made to the explanations for FIGS. 1 and 2.

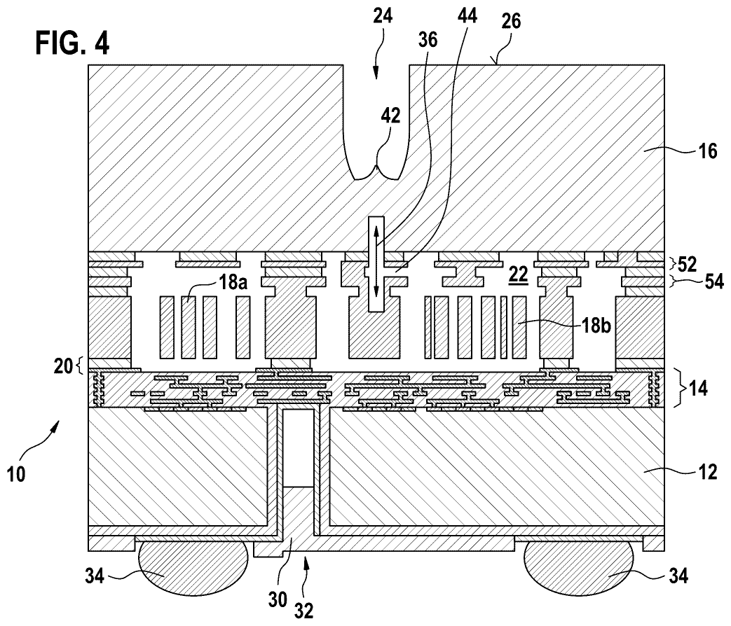

FIG. 4 shows a schematic representation of a final product for illustrating a fourth embodiment of the method for forming a bore for a cavity arranged within a semiconductor layer stack.

In the case of the embodiment described herein, the bore 38 is drilled into the access channel 44 extending in parallel with the bore exit surface 26 and framed by the cavity 22. In particular, the access channel 44 can be formed between a first material layer 52 and a second material layer 54, wherein the at least one MEMS component 18a and 18b is at least partially formed from the first material layer 52 and/or the second material layer 54. Similarly, the access channel 44 can be formed within a material layer (not shown) from which the at least one MEMS component 18a and 18b is also at least partially formed. In these cases as well, the access channel 44 also prevents the unwanted penetration of particles and fumes into the cavity 22.

With respect to further features of the method shown in FIG. 4 and its advantages, reference is made to the explanations for FIGS. 1 and 2.

Although the intermediate and end products are only shown as individual components in the figures above, the method steps described can also be executed at wafer level.

The semiconductor devices that can be realized by means of the present invention can be used in connection with smartphones and tablets, wearables, hearables, AR and VR, drones, gaming and toys, robots, smart homes and in an industrial context. Possible applications for such semiconductor devices can include wake-up functions for selected device modules, recognition of device orientation, screen orientation and display orientation, recognition of significant motion, shock and free-fall recognition, HMI (human-machine interface) functionality, such as, e.g., multi-tap recognition, activity recognition, gesture recognition, context recognition and user recognition, motion control, gimbal system, height and position stabilization, flight control, image stabilization, indoor and outdoor navigation, floor recognition, position tracking and route recording, PDR (pedestrian dead reckoning), dynamic route planning, boundary and obstacle recognition, indoor SLAM (simultaneous localization and mapping), intrusion monitoring, real-time motion detection, real-time motion tracking, activity tracking, pedometer, calorie counter, sleep monitoring. This can include the detection of the wearing condition of hearables (in-ear/out-of-ear detection), determination of head orientation and/or head movement, audio applications, speech recognition, keyword recognition, user recognition, active noise reduction, logistics, parts tracking, energy management, energy-saving measurement, predictive maintenance, air quality and climate monitoring, mold recognition, water level recognition and/or sensor data fusion. The semiconductor devices can also be used in connection with automotive applications. Examples include crash detection, e.g., in airbag systems, an electronic stability program (ESP), vehicle dynamics control (VDC), hill start assist, hill hold control (prevention of rolling back when starting off on inclines), adaptive chassis control, smart tires, e.g., road condition monitoring, road noise cancellation, navigation applications, autonomous driving, theft detection, alarm functions, control of the tailgate inclination, optimization of the engine control and/or optimization of the combustion process in gasoline-powered or diesel-powered engines.

What is claimed is:

1. A method for forming a bore for a cavity arranged within a semiconductor layer stack, the method comprising the following steps:
forming a first partial bore using a first laser ablation step started at an outer surface of the semiconductor layer stack in such a way that the first partial bore extends, with a first mean dimension aligned in parallel with the outer surface, partially through the semiconductor layer stack starting from the outer surface and is formed on a side directed away from the outer surface, the side directed away from the outer surface having a bottom surface of the first partial bore lying between the outer surface and the cavity; and
forming a second partial bore using a second laser ablation step started from the bottom surface of the first partial bore in such a way that the second partial bore extends with a second mean dimension aligned in parallel with the outer surface and smaller than the first mean dimension, through the bottom surface of the first partial bore: (i) into the cavity or (ii) into an access channel opening at the cavity or (iii) connected to the cavity via a connecting channel.

2. The method according to claim 1, wherein the first partial bore and the second partial bore are drilled through a semiconductor substrate of the semiconductor layer stack bounding the cavity, the substrate being equipped, on its substrate surface directed away from the outer surface of the semiconductor layer stack, with a circuit layer having at least one application-specific integrated circuit.

3. The method according to claim 1, wherein the first partial bore and the second partial bore are drilled through a capping substrate of the semiconductor layer stack, the capping substrate bounding the cavity.

4. The method according to claim 1, wherein the second partial bore is drilled into the access channel extending in parallel with the outer surface of the semiconductor layer stack through a part of the semiconductor layer stack.

5. The method according to claim 1, wherein the first partial bore and the second partial bore are aligned with respect to one another in such a way that a common central longitudinal axis can be defined for the first partial bore and the second partial bore.

6. The method according to claim 5, wherein a first length of the first partial bore along the common central longitudinal axis is greater by at least a factor of 2 than a second length of the second partial bore along the common central longitudinal axis.

7. The method according to claim 1, wherein the first partial bore is formed with the first mean dimension aligned in parallel with the outer surface, the first mean dimension being greater by at least a factor of 2 than the second mean dimension, with which the second partial bore is formed in parallel with the outer surface.

8. A method for enclosing a pressure and/or a medium in a cavity arranged within a semiconductor layer stack, the method comprising the following steps:
forming a bore for the cavity arranged within the semiconductor layer stack, including:
forming a first partial bore using a first laser ablation step started at an outer surface of the semiconductor layer stack in such a way that the first partial bore extends, with a first mean dimension aligned in parallel with the outer surface, partially through the semiconductor layer stack starting from the outer surface and is formed on a side directed away from the outer surface, the side directed away from the outer surface having a bottom surface of the first partial bore lying between the outer surface and the cavity, and
forming a second partial bore using a second laser ablation step started from the bottom surface of the first partial bore in such a way that the second partial bore extends with a second mean dimension aligned in parallel with the outer surface and smaller than the first mean dimension, through the bottom surface of the first partial bore: (i) into the cavity or (ii) into an access channel opening at the cavity or (iii) connected to the cavity via a connecting channel; and
sealing the bore when the pressure and/or the medium are present in the cavity by melting using a laser beam, a wall region of the first partial bore and/or the second partial bore of the bore, the wall region lying adjacent to the bottom surface of the first partial bore of the bore.

9. A semiconductor layer stack, comprising:
a cavity arranged within the semiconductor layer stack; and
a bore, including:
a first partial bore having laser ablation tracks, which extends with a first mean dimension aligned in parallel with an outer surface of the semiconductor layer stack, partially through the semiconductor layer stack starting from an outer surface and at least remnants of a bottom surface of the first partial bore lying between the outer surface and the cavity, on a side directed away from the outer surface; and
a second partial bore having laser ablation tracks, which extends with a second mean dimension aligned in parallel with the outer surface and smaller than the first mean dimension, through the bottom surface of the first partial bore: (i) into the cavity or (ii) into an access channel opening at the cavity or (iii) connected to the cavity via a connecting channel.

10. A semiconductor layer stack, comprising:
a cavity arranged within the semiconductor layer stack; and
a bore closure made from a melted and solidified partial material of the semiconductor layer stack, the bore closure lying between a first partial bore having laser ablation tracks and a second partial bore having laser ablation tracks;
wherein the first partial bore extends with a first mean dimension aligned in parallel with an outer surface of the semiconductor layer stack, partially through the semiconductor layer stack starting from the outer surface, and the second partial bore extends with a second mean dimension aligned in parallel with the outer surface and smaller than the first mean dimension: (i) into the cavity or (ii) into an access channel opening at the cavity or (iii) connected to the cavity via a connecting channel.
